(19) United States
(12) Patent Application Publication
(10) Pub. No.: US 2013/0148296 A1
(43) Pub. Date: Jun. 13, 2013

(54) PROTECTING JACKET FOR ELECTRONIC PRODUCT

(71) Applicants: CHI-HAN HUANG, New Taipei (TW); Chi-yuan Lee, New Taipei (TW); Hung-wei Yu, New Taipei (TW)

(72) Inventors: CHI-HAN HUANG, New Taipei (TW); Chi-yuan Lee, New Taipei (TW); Hung-wei Yu, New Taipei (TW)

(73) Assignee: Cheng Uei Precision Industry Co., LTD., New Taipei City (TW)

(21) Appl. No.: 13/324,995

(22) Filed: Dec. 13, 2011

(51) Int. Cl. H05K 7/20

(52) U.S. Cl. 361/688

(57) ABSTRACT

The present invention discloses a protecting jacket, which includes a protecting jacket body and a semiconductor cooler. The semiconductor cooler is disposed on an inner surface of the protecting jacket body. The semiconductor cooler includes a Peltier element, a thermistor sensor, a PWM controller, and a switching element. The PWM controller is respectively coupled to the thermistor sensor and the switching element, and the switching element is coupled to the Peltier element. A circuit is connected by the switching element for making the semiconductor cooler work when a temperature of an electronic product is higher than a constant value. In distinct contrast, the circuit is disconnected by the switching element for stopping the semiconductor cooler working when the temperature of the electronic product is lower than the constant value. Therefore, the electronic product can maintain a longer working time, and conserving energy is achieved.

### FIELD OF THE INVENTION

The present invention relates to a protecting jacket for an electronic product, and especially to a protecting jacket with a cooling function for an electronic product.

### BACKGROUND OF THE INVENTION

The electronic products are includes Tablet PCs, mobile phones, notebook computers, PDAs (Personal Digital Assistant), and so on. With a rapid growth and development in modern technology, the upgrading and updating of the electronic products are more and more quick. On one hand, the package dimension of the electronic products tends to miniaturization. On the other hand, the processing speeds of central processors within the electronic product become faster and faster, so that the accumulating heat in the bodies thereof is more and more when the electronic products are working If the heat can not be released to outsides in time, the working reliabilities of the electronic products will be greatly affected. Thus, for a small electronic product, how to effectively release the heat to the outside of the body for cooling the body becomes a problem to be solved urgently in the process of the miniaturization of the electronic products. In existing technology, corresponding heat abstractor is generally disposed in the electronic product or on a circuit board thereof. However, from the point of view of the actual operation, the cooling function has a strict limitation. The temperature of the body still may rise highly after long usage. In order to further explain the cooling of the electronic products, it is hoped that an external device can release the heat. For example, an electronic product bracket equipped with a fan, or a protecting jacket with cooling holes for an electronic product is developed. Conventional air cooling is generally employed in existing technology. The air cooling employs a fan to accelerate circulation of the air, and an additional fan needs to be installed. However, on one hand, a noise is developed; on the other hand, it is difficult for cooling the microminiaturized product by limiting the size thereof. It can not be the best cooling way from the point of view of the microminiaturized electronic products.

In a conventional cooling jacket for a heating electronic product, a heat abstracting pad is fixed on a bottom of a cavity of the cooling jacket, and located on an inner surface of the cooling jacket so as to contact an underside of the heating electronic product. The temperature of the heating electronic product can be controlled during the use through a heat-absorbing material placed in the cooling jacket. However, after the heating electronic product being used for a long time, the cooling jacket is apt to affect the heat dissipation of the electronic product because of the heat-absorbing material saturated with heat.

### SUMMARY OF THE INVENTION

Accordingly, an objective of the present invention is to provide a new protecting jacket for an electronic product. The protecting jacket for an electronic product has a semiconductor cooler for continuously cooling the electronic product.

To achieve the foregoing objective, the technical solution is implemented as follows.

A protecting jacket for an electronic product includes a protecting jacket body and a semiconductor cooler disposed on an inner surface of the protecting jacket body, wherein the semiconductor cooler comprises a Peltier element, a thermistor sensor, a pulse width modulation controller, and a switching element, the pulse width modulation controller respectively coupled to the thermistor sensor and the switching element, the switching element coupled to the Peltier element.

Preferably, the pulse width modulation (PWM) controller is coupled to a power input unit, and the power input unit is electrically coupled to a power output unit.

Preferably, the power output unit is a USB port of the electronic product.

In accordance with the protecting jacket for an electronic product provided by the present invention, a circuit is connected by the switching element for making the semiconductor cooler work when a temperature of the electronic product is higher than a constant value. In distinct contrast, the circuit is disconnected by the switching element for stopping the semiconductor cooler working when the temperature of the electronic product is lower than the constant value. Therefore, the electronic product can maintain a longer working time, and an objective of conserving energy is achieved.

It is to be understood that both the foregoing general description and the following detailed description of the present invention are exemplary and explanatory and are intended to provide further explanation of the invention as claimed.

### BRIEF DESCRIPTION OF THE DRAWINGS

FIG. 1 is a schematic drawing illustrating a general appearance of the protecting jacket for an electronic product;

FIG. 2 is a schematic drawing illustrating function blocks of the protecting jacket for an electronic product; and

FIG. 3 is a schematic drawing illustrating a circuit of the protecting jacket for an electronic product.

### DETAILED DESCRIPTION OF THE PREFERRED EMBODIMENTS

Reference will now be made in detail to a preferred embodiment of the invention, examples of which are illustrated in the accompanying drawings.

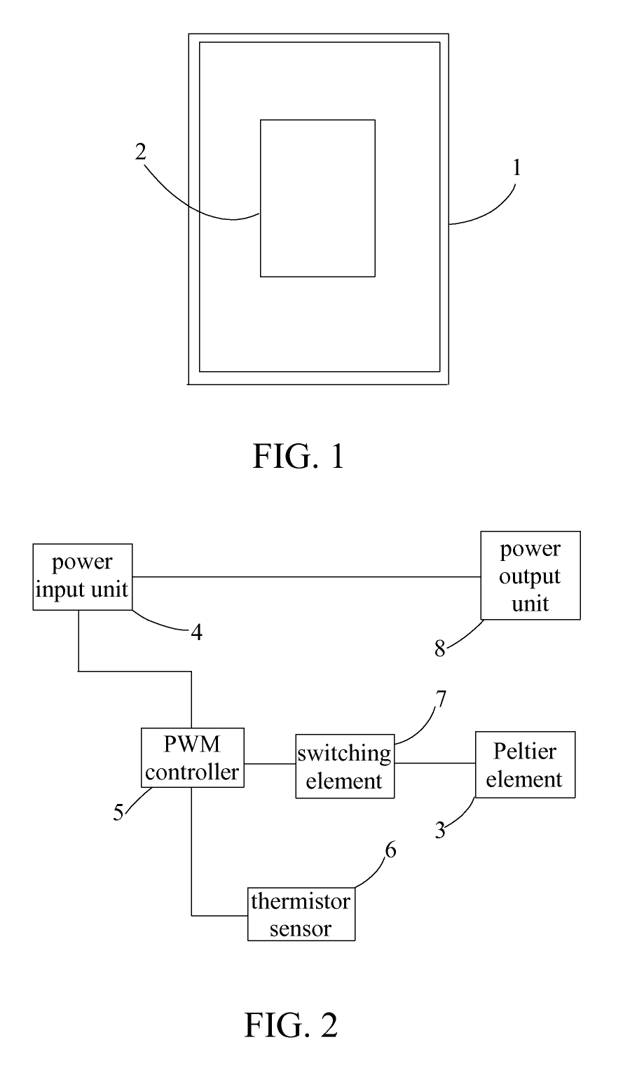

As shown in FIG. 1, a protecting jacket for an electronic product provided by the present invention includes a protecting jacket body 1 and a semiconductor cooler 2. The protecting jacket body 1 herein is disposed around a periphery of the electronic product for protecting the electronic product. The semiconductor cooler 2 is disposed on a surface (preferable to an inner surface which is attach to the electronic product) of the protecting jacket body 1 for continuously cooling the electronic product.

The semiconductor cooler 2 consists of a plurality of N-type and P-type semiconductor particles which are arranged sequentially on a microscopic level, and the N-type and P-type semiconductor particles are coupled to each other via conductors for forming a complete circuit. The conductor can be made of copper, aluminum or other metals. The N-type semiconductor and the P-type semiconductor are sandwiched together, such as a sandwich biscuit, by two insulative ceramic films with a good thermal conductivity, thereby forming an electrical couple. When an N-type semiconductor and a P-type semiconductor are coupled to form the electrical couple, then an energy transfer occurs after conducting a DC current. A joint by which the current flow from the N-type semiconductor to the P-type semiconductor will absorbs the heat to forming a cold terminal; another joint by which the current flow from the P-type semiconductor to the N-type semiconductor will release the heat to form a hot terminal. The amount of absorbing and releasing the heat is determined by the magnitude of the current and the number of N-type and the P-type semiconductor pairs. That is the work function of the semiconductor cooler 2.

A typical semiconductor cooler includes a Peltier element. The present invention provides a semiconductor structure utilizing the current to transfer the heat form one end to an opposite end. When the two semiconductors are combined together, a thermal conducting phenomenon occurs after conducting a DC current with a low voltage (5 to 15V or so). A semiconductor cooler designed according to this phenomenon is known as the Peltier element, which can be utilized for cooling the electronic product.

As shown in FIG. 2, the semiconductor cooler 2 includes a Peltier element 3, a thermistor sensor 6, a PWM controller 5, and a switching element 7. The PWM controller 5 is respectively coupled to the thermistor sensor 6 and the switching element 7; and the switching element 7 is coupled to the Peltier element 3. The thermistor sensor 6 is utilized to sense the temperature of the electronic product and transmit a signal to the PWM controller 5. The PWM controller 5 receives the sensed signal of the thermistor sensor 6 and controls on and off of a circuit on the Peltier element 3, thereby making the semiconductor cooler 2 work. Because the Peltier element 3 is a solid-state device that has no moving parts, the semiconductor cooler 2 doesn't make any noise while working In addition, the useful life of the Peltier element 3 can be longer than two hundred thousand hours, thus it has higher reliability.

If a temperature of the electronic product is higher than a constant value, the thermistor sensor 6 will dispatch a signal to the PWM controller 5, thereby making the switching element 7 switch on the circuit. In distinct contrast, if the temperature of the electronic product is lower than a constant value, the thermistor sensor 6 will dispatch a signal to the PWM controller 5, thereby making the switching element 7 switch off the circuit. Accordingly, the thermistor sensor 6 and PWM controller 5 are combined to control the work of the semiconductor cooler 2, and they can realize a smart on/off function for the semiconductor cooler 2. While ensuring that the temperature of the electronic product is lowered, the electronic product can maintain a longer working time, and an objective of conserving energy is achieved.

The semiconductor cooler 2 provided by the present invention requires coupling to a power input unit 4 for obtaining power supply. The power input unit 4 is electrically coupled to a power output unit 8. The power output unit 8 herein can be a battery, or be a power outputted from a USB port of the electronic product , or be any other power being able to provide a direct current. Preferably, the power output unit 8 employs the USB port of the electronic product to serve as the power output unit, thereby ensuring the portability of the electronic product and the protecting jacket thereof.

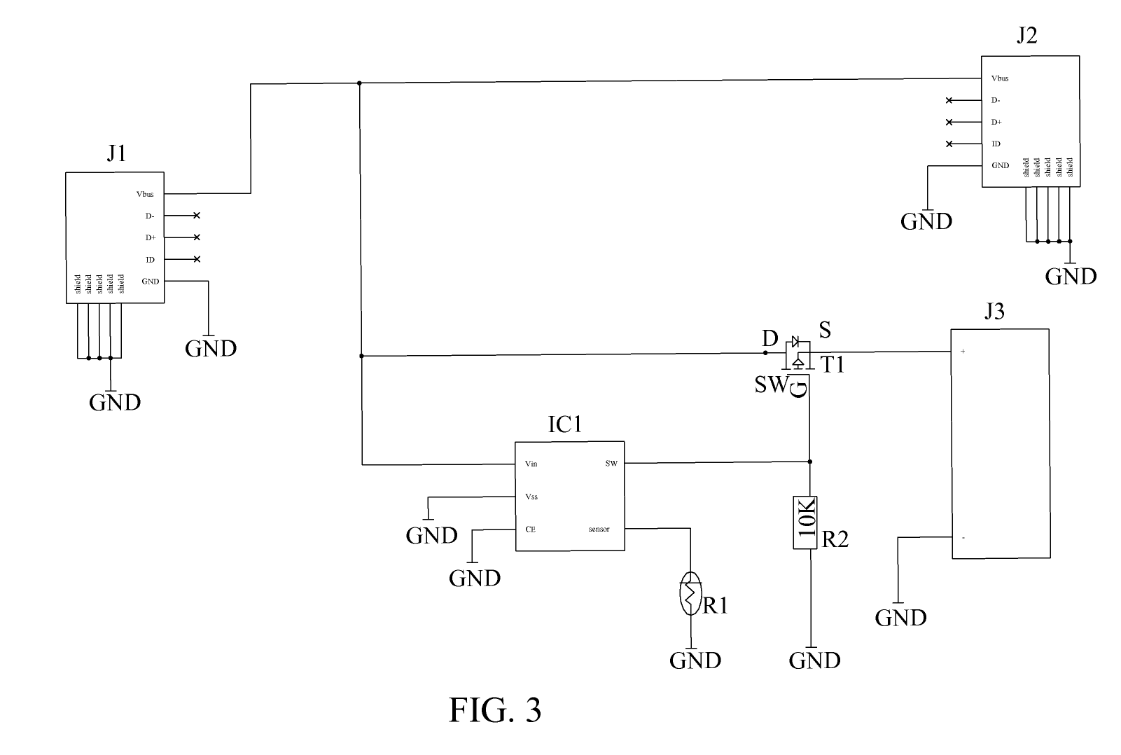

As shown in FIG. 3, USB ports (J1 and J2) are served as the power input unit 4 and the power output unit 8, and a closed loop that contains a Peltier unit (J3) served as the Peltier element 3, a PWM control unit (IC1) served as the PWM controller 5, a thermistor (R1) served as the thermistor sensor 6, and a switch T1 served as the switching element 7 can be formed for provide the direct current for said semiconductor cooler 2.

While the preferred embodiments of the present invention have been illustrated and described in detail, various modifications and alterations can be made by persons skilled in this art. The embodiment of the present invention is therefore described in an illustrative but not restrictive sense.

What is claimed is:

1. A protecting jacket for an electronic product, comprising:
a protecting jacket body and a semiconductor cooler disposed on a inner surface of the protecting jacket body;
wherein the semiconductor cooler comprises a Peltier element, a thermistor sensor, a pulse width modulation controller, and a switching element, the pulse width modulation controller respectively coupled to the thermistor sensor and the switching element, the switching element coupled to the Peltier element.

2. The protecting jacket of claim 1, wherein the pulse width modulation controller is coupled to a power input unit, and the power input unit is electrically coupled to a power output unit.

3. The protecting jacket of claim 2, wherein the power output unit is a Universal Serial Bus (USB) port of the electronic product.
